(19) United States
(12) Patent Application Publication
(10) Pub. No.: US 2026/0163399 A1
(43) Pub. Date: Jun. 11, 2026

(54) DEVICE AND METHOD FOR MONITORING SECONDARY BATTERY

(71) Applicant: Samsung SDI Co., Ltd., Yongin-si (KR)

(72) Inventors: Jin Kim, Yongin-si (KR); Jongtaek Park, Yongin-si (KR); Hyunsung Kim, Yongin-si (KR); Eunseon Shin, Yongin-si (KR); Mingon Son, Yongin-si (KR)

(73) Assignee: Samsung SDI Co., Ltd., Yongin-si (KR)

(21) Appl. No.: 19/179,818

(22) Filed: Apr. 15, 2025

(30) Foreign Application Priority Data
Oct. 18, 2024 (KR) 10-2024-0143134

(51) Int. Cl. H02J 7/90; G01K 3/14; G01R 31/3835; H01M 10/42; H01M 10/44

(52) U.S. Cl. CPC H02J 7/977; G01K 3/14; G01R 31/3835; H01M 10/4285; H01M 10/443

(57) ABSTRACT

The present disclosure relates to a device and method for monitoring a secondary battery. The device for monitoring a secondary battery may include a charger/discharger connected to electrode terminals of a secondary battery and configured to measure a voltage of the secondary battery or apply a current to the secondary battery, a temperature measurement part configured to measure temperatures of the secondary battery and the charger/discharger, a temperature adjustment part configured to adjust the temperature of the charger/discharger, and a control part configured to control the temperature adjustment part, wherein the control part is configured to adjust the temperature of the charger/discharger by controlling the temperature adjustment part based on temperature information received from the temperature measurement part.

### CROSS-REFERENCE TO RELATED APPLICATIONS

This present application claims priority to and the benefit under 35 U.S.C. § 119(a)-(d) of Korean Patent Application No. 10-2024-0143134, filed on Oct. 18, 2024, in the Korean Intellectual Property Office, the entire disclosure of which is incorporated herein by reference.

### FIELD

Aspects of embodiments of the present disclosure relate to a device and method for monitoring a secondary battery.

### BACKGROUND

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

The above information disclosed in this Background section is for enhancement of understanding of the background of the present disclosure, and therefore, it may contain information that does not constitute related (or prior) art.

### SUMMARY

Embodiments of the present disclosure provide a device and method for monitoring a secondary battery which may solve one or more problems described herein.

These and other aspects and features of the present disclosure will be described in or will be apparent from the following description of embodiments of the present disclosure.

A secondary battery monitoring device according to one or more embodiments of the present disclosure for solving one or more technical problems may include a charger/discharger connected to electrode terminals of a secondary battery and configured to measure a voltage of the secondary battery or apply a current to the secondary battery, a temperature measurement part configured to measure temperatures of the secondary battery and the charger/discharger, a temperature adjustment part configured to adjust the temperature of the charger/discharger, and a control part configured to control the temperature adjustment part, wherein the control part is configured to adjust the temperature of the charger/discharger by controlling the temperature adjustment part based on temperature information received from the temperature measurement part.

According to one or more embodiments of the present disclosure, the temperature adjustment part may include a heating device disposed in the charger/discharger, and the control part may be further configured to heat the charger/discharger by controlling the heating device if the temperature of the charger/discharger received from the temperature measurement part is lower than or equal to the temperature of the secondary battery.

According to one or more embodiments of the present disclosure, the temperature adjustment part may include a cooling device disposed in the charger/discharger, and the control part may be further configured to cool the charger/discharger by controlling the cooling device if the temperature of the charger/discharger received from the temperature measurement part is higher than the temperature of the secondary battery.

According to one or more embodiments of the present disclosure, the heating device may include at least one of a wire heater, a ribbon heater, or a film heater.

According to one or more embodiments of the present disclosure, the cooling device may include at least one of a cooling flow path or a thermoelectric element.

According to one or more embodiments of the present disclosure, the secondary battery may include a first electrode terminal and a second electrode terminal, the charger/discharger may include a first electrode pin and a second electrode pin, the first electrode pin may be connected to the first electrode terminal, and the second electrode pin may be connected to the second electrode terminal.

According to one or more embodiments of the present disclosure, the control part may be further configured to receive a reference value regarding a temperature difference between the secondary battery and the charger/discharger.

According to one or more embodiments of the present disclosure, the reference value may be a value obtained based on temperature information according to charging/discharging conditions of a secondary battery module unit.

According to one or more embodiments of the present disclosure, the temperature adjustment part may include a heating device, and the control part may be further configured to heat the charger/discharger by controlling the heating device if the temperature difference between the charger/discharger and the secondary battery received from the temperature measurement part is less than or equal to the reference value.

According to one or more embodiments of the present disclosure, the temperature adjustment part may include a cooling device, and the control part may be further configured to cool the charger/discharger by controlling the cooling device if the temperature difference between the charger/discharger and the secondary battery received from the temperature measurement part is higher than the reference value.

A method of monitoring a secondary battery according to one or more embodiments of the present disclosure for solving one or more technical problems may include performing charging and discharging of a secondary battery by a charger/discharger connected to electrode terminals of the secondary battery, measuring temperatures of the secondary battery and the charger/discharger, and adjusting the temperature of the charger/discharger based on the measured temperature of the secondary battery and the measured temperature of the charger/discharger.

According to one or more embodiments of the present disclosure, the adjusting the temperature of the charger/discharger may include heating the charger/discharger in response to determining that the temperature of the charger/discharger is lower than or equal to the temperature of the secondary battery.

According to one or more embodiments of the present disclosure, the adjusting the temperature of the charger/discharger may include cooling the charger/discharger in response to determining that the temperature of the charger/discharger is higher than the temperature of the secondary battery.

According to one or more embodiments of the present disclosure, the charger/discharger may be heated by at least one of a wire heater, a ribbon heater, or a film heater installed in the charger/discharger.

According to one or more embodiments of the present disclosure, the charger/discharger may be cooled by at least one of a cooling flow path or a thermoelectric element installed in the charger/discharger.

According to one or more embodiments of the present disclosure, the secondary battery may include a first electrode terminal and a second electrode terminal, the charger/discharger may include a first electrode pin and a second electrode pin, the first electrode pin may be connected to the first electrode terminal, and the second electrode pin may be connected to the second electrode terminal.

According to one or more embodiments of the present disclosure, the method of monitoring a secondary battery may further include receiving a reference value regarding a temperature difference between the secondary battery and the charger/discharger.

According to one or more embodiments of the present disclosure, the reference value may be a value obtained based on temperature information according to charging/discharging conditions of a secondary battery module unit.

According to one or more embodiments of the present disclosure, the adjusting the temperature of the charger/discharger may include heating the charger/discharger in response to determining that the temperature difference between the charger/discharger and the secondary battery is less than or equal to the reference value.

According to one or more embodiments of the present disclosure, the adjusting the temperature of the charger/discharger may include cooling the charger/discharger in response to determining that the temperature difference between the charger/discharger and the secondary battery is higher than the reference value.

The secondary battery monitoring device according to some embodiments of the present disclosure can implement, also in the cell unit evaluation method of the secondary battery, the heat-generating/cooling phenomenon by the busbars that can occur in the module unit evaluation method. As a result, the performance prediction accuracy in module units can be improved, and the characteristics of the secondary battery under actual use conditions can be monitored effectively.

However, aspects and features of the present disclosure are not limited to those described above, and other aspects and features not mentioned will be clearly understood by a person skilled in the art from the detailed description, described herein.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

FIG. 1 is a schematic diagram showing a configuration of a secondary battery monitoring device according to embodiments of the present disclosure;

FIG. 2 is a block diagram showing an example of a control part according to embodiments of the present disclosure;

FIGS. 3A and 3B are diagrams showing an example of electrode pins according to embodiments of the present disclosure;

FIGS. 4A and 4B are diagrams showing an example of electrode pins according to embodiments of the present disclosure;

FIG. 5 is a diagram showing an example of a temperature profile in a cell unit evaluation method;

FIG. 6 is a diagram showing an example of a temperature profile in a module unit evaluation method;

FIG. 7 is a flowchart showing an example of a secondary battery monitoring method according to embodiments of the present disclosure;

FIG. 8 is a flowchart showing an example in which a method of adjusting the temperature of a charger/discharger is performed according to embodiments of the present disclosure; and

FIG. 9 is a flowchart showing an example in which a method of adjusting the temperature of a charger/discharger is performed according to embodiments of the present disclosure.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meanings and concepts consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C,” “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (or under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

Singular expressions herein include plural expressions, unless the context clearly specifies that they are singular. Further, plural expressions include singular expressions, unless the context clearly specifies that they are plural. When a part is said to include a component throughout the specification, this does not mean to exclude other components but may mean to further include other components unless specifically stated to the contrary.

In the present disclosure, the sizes and relative sizes of the areas shown in the drawings may have been exaggerated for clarity of description. For example, the sizes shown in the drawings are merely for ease of understanding and are not limited thereto. Further, the flowcharts shown in the drawings and the descriptions thereof are merely examples and may be implemented differently in some embodiments. For example, one or more steps may be omitted, the order of each step may be changed, one or more steps may be performed in an overlapping manner, or one or more steps may be performed repetitively multiple times.

A commonly used method for evaluating the performance of a battery cell is to place the cell in a constant-temperature chamber and then perform a charging/discharging test via charging/discharging pins. However, this evaluation method is limited to checking the performance of individual cells only and may not fully reflect various environmental factors that may occur in an actual module.

Because the battery performance in a module unit is determined by various factors that affect the interaction between cells and the current flow, existing methods cannot fully implement problems that may occur in a module, and may thus have limitations in evaluating actual performance changes in the module. Therefore, it is desirable to have an evaluation method that takes into account the thermal interaction between cells during charging/discharging of module units.

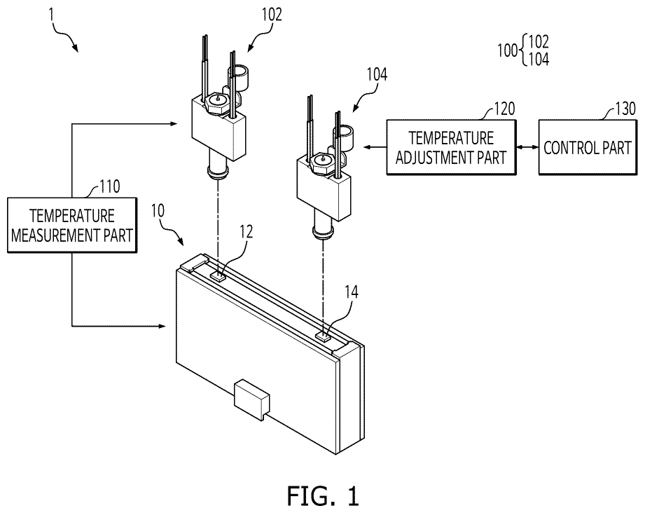

FIG. 1 is a schematic diagram showing the configuration of a secondary battery monitoring device 1 according to embodiments of the present disclosure. Referring to FIG. 1, the secondary battery monitoring device 1 may include a charger/discharger 100 connected to a secondary battery 10, a temperature measurement part 110, a temperature adjustment part 120, and a control part 130.

The charger/discharger 100 may be connected to the electrode terminals of the secondary battery 10 and measure the voltage of the secondary battery 10 or apply current to the secondary battery 10. The charger/discharger may perform charging and discharging of the secondary battery 10. In embodiments, the charger/discharger 100 may include a first electrode pin 102 and a second electrode pin 104, and the secondary battery 10 may include a first electrode terminal 12 and a second electrode terminal 14. Here, the first electrode terminal 12 and the second electrode terminal 14 may have different polarities. The first electrode pin 102 may be connected to the first electrode terminal, and the second electrode pin 104 may be connected to the second electrode terminal. The shape of the charger/discharger 100 is shown in FIG. 1 but is not limited thereto. The charger/discharger 100 may be implemented in various shapes that can be connected to the electrode terminals of the secondary battery 10 and measure the voltage of the secondary battery 10 or apply the current of the secondary battery 10.

The temperature measurement part 110 may measure the temperatures of the secondary battery 10 and the charger/discharger 100. In embodiments, the temperature measurement part 110 may be disposed in the secondary battery 10 or the charger/discharger 100 and may measure the temperature of the secondary battery 10 or the charger/discharger 100. In contrast, the temperature measurement part 110 may not be disposed in the secondary battery 10 or the charger/discharger 100, and may measure the temperature of the secondary battery 10 or the charger/discharger 100 in a non-contact manner. The present disclosure does not limit the temperature measurement method. The temperature measurement part 110 may transmit information on the temperature of the secondary battery 10 and the temperature of the charger/discharger 100 measured to the control part 130.

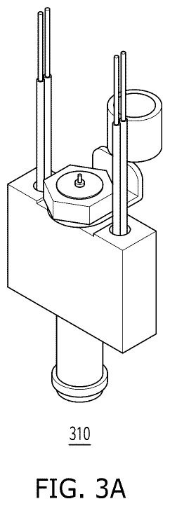

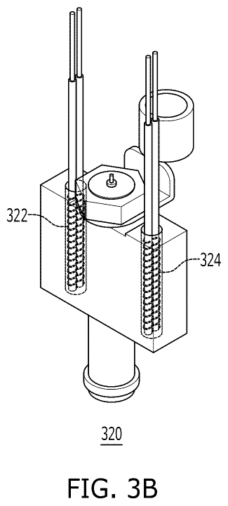

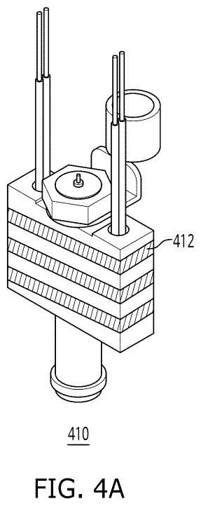

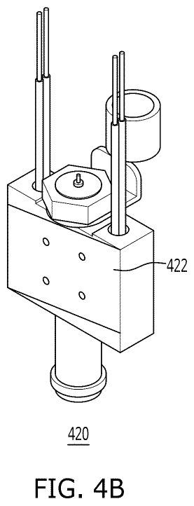

The temperature adjustment part 120 may adjust the temperature of the charger/discharger 100 based on a control signal received from the control part 130. In embodiments, the temperature adjustment part 120 may include a heating device. Here, the heating device may be disposed in the charger/discharger 100. By having the heating device disposed in the charger/discharger 100, the temperature adjustment part 120 may adjust the temperature of the charger/discharger 100 according to a command from the control part 130. As a specific example of the heating device, at least one of a wire heater, a ribbon heater, or a film heater may be included. A specific example of the heating device will be described later with reference to FIGS. 3A to 3B and 4A to 4B.

In embodiments, the temperature adjustment part 120 may include a cooling device. Here, the cooling device may be disposed in the charger/discharger 100. By having the cooling device disposed in the charger/discharger 100, the temperature adjustment part 120 may adjust the temperature of the charger/discharger 100 according to a command from the control part 130. As a specific example of the cooling device, at least one of a cooling flow path or a thermoelectric element may be included.

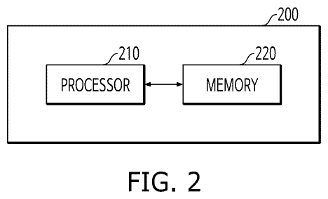

The control part 130 may receive temperature information of the secondary battery 10 and the charger/discharger 100 from the temperature measurement part 110. The control part 130 may control the temperature adjustment part 120 based on the temperature information of the secondary battery 10 and the charger/discharger 100 received from the temperature measurement part 110. The control part 130 may be configured to adjust the temperature of the charger/discharger 100 by controlling the temperature adjustment part 120. The detailed configuration of the control part 130 will be described later in relation to FIG. 2.

In embodiments, the control part 130 may be configured to heat the charger/discharger 100 by controlling the temperature adjustment part 120 if the temperature of the charger/discharger 100 received from the temperature measurement part 110 is o than or equal to the temperature of the secondary battery 10. As a specific example, the control part 130 may be configured to heat the charger/discharger 100 by controlling the heating device included in the temperature adjustment part 120. As another example, the control part 130 may be configured to heat the charger/discharger 100 by stopping the operation of the cooling device included in the temperature adjustment part 120. The method by which the control part 130 adjusts the temperature of the charger/discharger 100 is not limited thereto.

In embodiments, the control part 130 may be configured to cool the charger/discharger 100 by controlling the temperature adjustment part 120 if the temperature of the charger/discharger 100 received from the temperature measurement part 110 is higher than the temperature of the secondary battery 10. As a specific example, the control part 130 may be configured to cool the charger/discharger 100 by controlling the cooling device included in the temperature adjustment part 120. As another example, the control part 130 may be configured to cool the charger/discharger 100 by stopping the operation of the heating device included in the temperature adjustment part 120. The method by which the control part 130 adjusts the temperature of the charger/discharger 100 is not limited thereto.

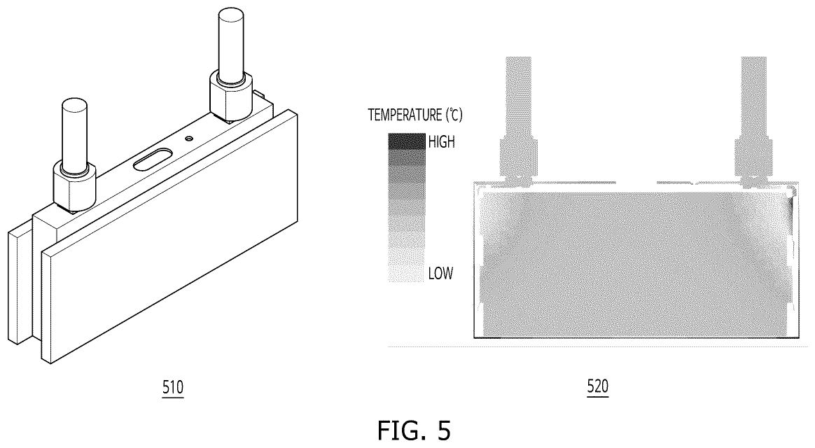

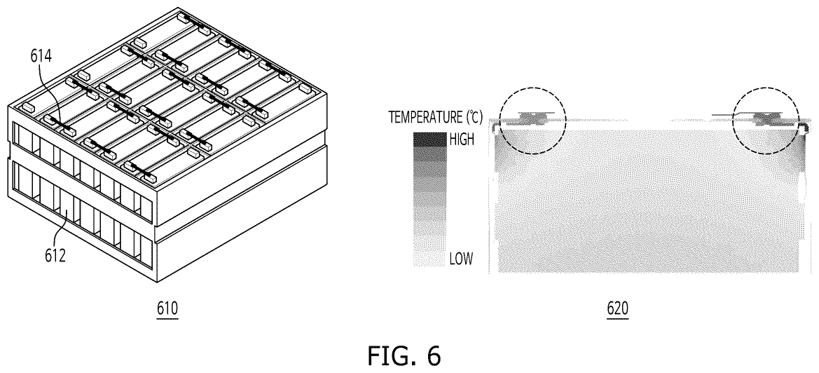

In embodiments, the control part 130 may be configured to receive a reference value regarding the temperature difference between the secondary battery 10 and the charger/discharger 100. Here, the reference value may be a value obtained based on temperature information according to the charging/discharging conditions of the secondary battery module unit. In one example, the reference value may refer to a temperature of a busbar included in the secondary battery module minus a temperature of a unit cell included in the secondary battery module, under a charge and discharge condition of the secondary battery module units. However, the present disclosure is not limited thereto. As will be described later through FIGS. 5 and 6, when charging/discharging the secondary battery 10, the heat-generating portion and heat-generating level of the secondary battery 10 that is charged/discharged in cell units and the secondary battery 10 that is charged/discharged in module units may be different. Therefore, in order to create a module-unit charging/discharging environment even when charging/discharging in cell units, the control part may receive a reference value regarding the temperature difference between the secondary battery 10 and the charger/discharger 100.

In embodiments, the control part 130 may be configured to heat the charger/discharger 100 by controlling the temperature adjustment part 120 if the temperature difference between the charger/discharger 100 and the secondary battery 10 received from the temperature measurement part 110 is less than or equal to the reference value. As a specific example, the control part 130 may be configured to heat the charger/discharger 100 by controlling the heating device included in the temperature adjustment part 120. As another example, the control part 130 may be configured to heat the charger/discharger 100 by stopping the operation of the cooling device included in the temperature adjustment part 120. The method by which the control part 130 adjusts the temperature of the charger/discharger 100 is not limited thereto.

In embodiments, the control part 130 may be configured to cool the charger/discharger 100 by controlling the temperature adjustment part 120 if the temperature difference between the charger/discharger 100 and the secondary battery 10 received from the temperature measurement part 110 is higher than the reference value. As a specific example, the control part 130 may be configured to cool the charger/discharger 100 by controlling the cooling device included in the temperature adjustment part 120. As another example, the control part 130 may be configured to cool the charger/discharger 100 by stopping the operation of the heating device included in the temperature adjustment part 120. The method by which the control part 130 adjusts the temperature of the charger/discharger 100 is not limited thereto.

In contrast, the cell unit evaluation method of the secondary battery 10 may not be able to fully reflect the environmental factors in the module unit evaluation method. For example, in the module unit evaluation method, the busbars connecting cells may result in heat generation in the process of current flow, and this heat generation may affect the temperature and performance of the neighboring cells. Further, cooling by the busbars may occur depending on the module configuration, and this cooling may affect the temperature and performance of the neighboring cells.

As described herein, the control part 130 may be configured to adjust the temperature of the charger/discharger 100 by controlling the temperature adjustment part 120 based on the temperature information received from the temperature measurement part 110. The location where the charger/discharger 100 is disposed may correspond to the location where the busbar is disposed when the secondary battery 10 is modularized. Through this configuration, the heat-generating/cooling phenomenon by the busbars that occurs in the module unit evaluation method can be implemented in the cell unit evaluation method as well in the secondary battery 10. As a result, the performance prediction accuracy in module units can be improved, and the characteristics of the secondary battery under actual use conditions can be monitored effectively.

FIG. 2 is a block diagram showing an example of a control part 200 according to embodiments of the present disclosure. Referring to FIG. 2, the control part 200 according to embodiments of the present disclosure may include a memory 220 in which instructions are stored, and a processor 210 that executes the instructions stored in the memory 220. However, the present disclosure is not limited thereto. The control part 200 may further include other components in addition to the processor 210 and the memory 220.

The processor 210 may control the control part 200 overall, and may perform various data processing or calculations. As at least part of the data processing or calculations, the processor 210 may store commands or data received from other components in the memory 220, process the commands or data stored in the memory 220, and store the result data in the memory 220. The operations performed by the processor 210 may be referred to as operations performed by the control part 200. Similarly, the operations performed by the control part 200 may be referred to as operations performed by the processor 210.

The processor 210 should be construed broadly to encompass general-purpose processors, central processing units (CPUs), microprocessors, digital signal processors (DSPs), controllers, microcontrollers, state machines, etc. In some contexts, the processor 210 may refer to application-specific integrated circuits (ASICs), programmable logic devices (PLDs), field programmable gate arrays (FPGAs), etc. The processor 210 may also refer to a combination of processing devices such as, for example, a combination of a DSP and a microprocessor, a combination of a plurality of microprocessors, a combination of one or more microprocessors in combination with a DSP core, or a combination of any other such components.

The processor 210 may be configured to process commands of computer programs by performing basic arithmetic, logic, and input/output operations. According to some embodiments of the present disclosure, the processor 210 may receive temperature information on the secondary battery 10 and the charger/discharger 100 from the temperature measurement part 110. Further, the processor 210 may determine the temperature condition of the charger/discharger 100 based on the temperature information on the secondary battery 10 and the charger/discharger 100 received from the temperature measurement part 110, and transmit a control signal for controlling an operation according thereto to the temperature adjustment part 120.

The memory 220 may store information necessary for the processor 210 to operate. For example, the memory 220 may store instructions to be executed by the processor 210, and may also store relevant information received, obtained, and/or generated while the software or program is executed in the control part 200. For example, the memory 220 may store temperature information on the secondary battery 10 and the charger/discharger 100 received from the temperature measurement part 110.

The memory 220 should be construed broadly to encompass any electronic component capable of storing electronic information. The memory 220 may also refer to various types of processor-readable media, such as random-access memory (RAM), read-only memory (ROM), non-volatile random-access memory (NVRAM), programmable read-only memory (PROM), erasable-programmable read-only memory (EPROM), electrically erasable PROM (EEPROM), flash memory, magnetic or optical data storage, registers, etc. The memory 220 is said to be in electronic communication with the processor 210 if the processor 210 can read information from and/or write information to the memory 220. The memory 220 integrated into the processor 210 is in electronic communication with the processor 210.

In embodiments, the memory 220 may include any non-transitory computer-readable recording medium. According to embodiments, the memory 220 may include a permanent mass storage device. As another example, the permanent mass storage device may be included in the secondary battery monitoring device 1 or may be included in a device that can be accessed with wire or wirelessly by the secondary battery monitoring device 1, as a separate persistent storage device distinct from the memory. As yet another example, the memory 220 may be implemented by being included in the processor 210.

According to embodiments, the memory 220 may store an operating system and at least one program code (e.g., program code for monitoring temperature information and controlling operations). Further, the memory 220 may store the temperature information on the secondary battery 10 and the charger/discharger 100 from the temperature measurement part 110. Moreover, the memory 220 may store the reference value regarding the temperature difference between the secondary battery 10 and the charger/discharger 100 received from the processor 210 and/or an external device.

FIG. 3A is a diagram showing an example of electrode pins according to embodiments of the present disclosure. FIG. 3B is a diagram showing an example of electrode pins according to embodiments of the present disclosure. FIG. 4A is a diagram showing an example of electrode pins according to embodiments of the present disclosure. FIG. 4B is a diagram showing an example of electrode pins according to embodiments of the present disclosure.

In embodiments, the charger/discharger 100 may include a first electrode pin 102 and a second electrode pin 104. Referring to FIGS. 3A and 3B, an example of the first electrode pin 102 and/or the second electrode pin 104 is shown. The first electrode pin 102 and/or the second electrode pin 104 may be implemented in shapes such as an electrode pin 310 or an electrode pin 320, but the present disclosure is not limited to the specific shapes.

In embodiments, the electrode pin 310 may measure the voltage of the secondary battery 10 by using pins installed at the top thereof. Here, the pins installed at the top of the electrode pin 310 may be connected to the electrode terminals (e.g., the first electrode terminal 12 and the second electrode terminal 14) of the secondary battery 10.

In embodiments, the temperature adjustment part 120 may include a heating device. Specific examples of the heating device are shown in FIGS. 3A to 3B and 4A to 4B. According to some examples, the heating device may be wire heaters 322 and 324. Here, the wire heaters 322 and 324 may be disposed to wrap around the periphery of the pins installed at the top of the electrode pin 320. The wire heaters 322 and 324 may be disposed to wrap around the periphery of the pins installed at the top of the electrode pin 320 inside the electrode pin 320, as shown in FIG. 3B. However, the present disclosure is not limited thereto, and the wire heaters 322 and 324 may be exposed to the outside of the electrode pin 320.

Referring to FIG. 4A, according to some examples, the heating device may be a ribbon heater 412 type. The ribbon heater 412 may be disposed to wrap around the periphery of the electrode pin 410. The ribbon heater 412 may serve to heat the electrode pin 410 through heat generation. The ribbon heater 412 may be an electric heating element in the form of a thin and long ribbon, and may be a heating device that heats the surroundings by utilizing the resistance heat generated when an electric current flows through it.

According to some examples, the heating device may be a film heater 422 type. The film heater 422 may be disposed on at least one face of the electrode pin 420. The film heater 422 may serve to heat the electrode pin 420 through heat generation. The film heater 422 can heat the electrode pin 420 by utilizing the resistance heat generated when an electric current flows through it, and the heat transfer efficiency can be improved by having it in close contact with the electrode pin 420.

The heating device is shown to be the wire heaters 322 and 324, the ribbon heater 412, or the film heater 422 in FIGS. 3A to 3B and 4A to 4B, but the present disclosure is not limited thereto. The heating device may be implemented by various means capable of transferring heat to the charger/discharger 100.

FIG. 5 is a diagram showing an example of a temperature profile in a cell unit evaluation method. FIG. 6 is a diagram showing an example of a temperature profile in a module unit evaluation method. Referring to FIG. 5, an example of a configuration 510 for a cell unit evaluation method and an example of a temperature profile 520 of a secondary battery in the cell unit evaluation method configuration 510 can be seen. Referring to FIG. 6, an example of a configuration 610 for a module unit evaluation method and an example of a temperature profile 620 of a secondary battery in the module unit evaluation method configuration 610 can be seen.

Referring to FIG. 5, it can be seen that the temperature profile 520 of the secondary battery in the cell unit evaluation method configuration 510 is uniform in general. Even if heat is generated in the secondary battery in a single cell, the heat-generating action through the electrode pin can be performed smoothly. Further, because the unit cells are not disposed adjacent to each other, the influence from neighboring cells may not be significant.

In contrast, referring to FIG. 6, it can be seen that a plurality of unit cells 612 is connected via busbars 614 in the module unit evaluation method configuration 610. Further, it can be seen that each of the plurality of unit cells 612 is disposed adjacent to each other in the module frame. As a result, it can be seen that the heat generation is concentrated on the busbar 614 portions in the temperature profile 620 of the secondary battery in the module unit evaluation method configuration 610.

The secondary battery monitoring device 1, according to embodiments of the present disclosure, may have the temperature adjustment part 120 disposed in the charger/discharger 100, and the control part 130 may control the temperature adjustment part 120 based on the temperature information of the secondary battery 10 and the charger/discharger 100. Through this configuration, the heat-generating/cooling phenomenon by the busbars that occurs in the module unit evaluation method can be implemented in the cell unit evaluation method as well. As a result, the performance prediction accuracy in module units can be improved, and the characteristics of the secondary battery under actual use conditions can be monitored effectively.

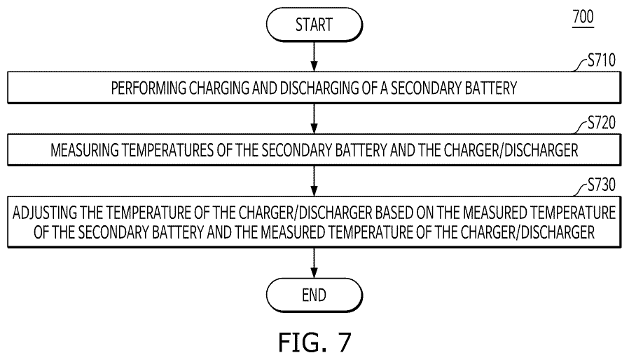

FIG. 7 is a flowchart showing an example of a secondary battery monitoring method 700 according to embodiments of the present disclosure.

First, the secondary battery monitoring method 700 may begin by performing charging and discharging of a secondary battery (act S710). Here, the charging and discharging of the secondary battery may be measured by a charger/discharger connected to the electrode terminals of the secondary battery. In embodiments, the secondary battery may include a first electrode terminal and a second electrode terminal, and the charger/discharger may include a first electrode pin and a second electrode pin. Here, the first electrode terminal and the second electrode terminal may have different polarities. Further, the first electrode pin of the charger/discharger may be connected to the first electrode terminal of the secondary battery, and the second electrode pin of the charger/discharger may be connected to the second electrode terminal of the secondary battery. The charging and discharging of the secondary battery may be performed by a plurality of electrode pins of the charger/discharger.

Next, the temperatures of the secondary battery and the charger/discharger may be measured (act S720). Here, the temperatures of the secondary battery and the charger/discharger may be measured by a temperature measurement part. In embodiments, the temperature measurement part may be disposed in the secondary battery or the charger/discharger and may measure the temperature of the secondary battery or the charger/discharger. In contrast, the temperature measurement part may not be disposed in the secondary battery or the charger/discharger, and may measure the temperature of the secondary battery or the charger/discharger in a non-contact manner. The present disclosure does not limit the temperature measurement method. The temperature measurement part may transmit information on the temperature of the secondary battery and the temperature of the charger/discharger measured to the control part.

Next, the temperature of the charger/discharger may be adjusted based on the measured temperature of the secondary battery and the measured temperature of the charger/discharger (act S730). Here, the temperature adjustment of the charger/discharger may be performed by the temperature adjustment part and/or the control part. For example, the control part may transmit a control signal to the temperature adjustment part based on the temperature of the secondary battery and the temperature of the charger/discharger received from the temperature measurement part. The temperature adjustment part may adjust the temperature of the charger/discharger in response to transmitting the control signal from the control part.

In embodiments, the temperature adjustment part may include a heating device. Here, the heating device may be disposed in the charger/discharger. By having the heating device disposed in the charger/discharger, the temperature adjustment part may adjust the temperature of the charger/discharger according to a command from the control part. As a specific example of the heating device, at least one of a wire heater, a ribbon heater, or a film heater may be included.

In embodiments, the temperature adjustment part may include a cooling device. Here, the cooling device may be disposed in the charger/discharger. By having the cooling device disposed in the charger/discharger, the temperature adjustment part may adjust the temperature of the charger/discharger according to a command from the control part. As a specific example of the cooling device, at least one of a cooling flow path or a thermoelectric element may be included.

The flowchart in FIG. 7 and the foregoing description are merely examples of the present disclosure, and the scope of the present disclosure is not limited to the flowchart in FIG. 7 and the foregoing description. For example, one or more steps in the flowchart and the foregoing description may be added, modified, and/or deleted, the order of one or more steps may be changed, and one or more steps may be performed simultaneously.

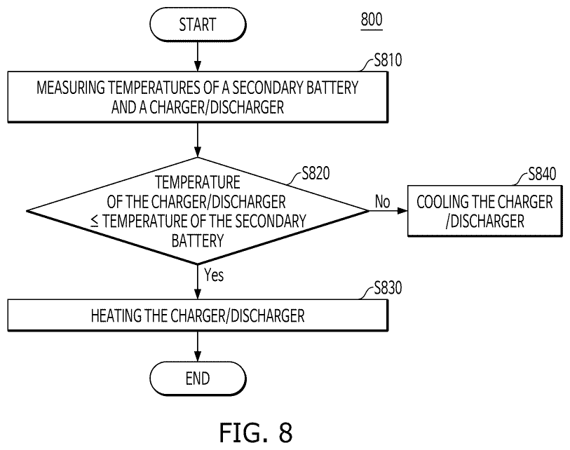

FIG. 8 is a flowchart showing an example in which a method 800 of adjusting the temperature of a charger/discharger is performed according to embodiments of the present disclosure.

First, the method 800 of adjusting the temperature of a charger/discharger may begin by measuring the temperatures of a secondary battery and a charger/discharger (act S810). Here, the temperatures of the secondary battery and the charger/discharger may be measured by a temperature measurement part. In embodiments, the temperature measurement part may be disposed in the secondary battery or the charger/discharger and may measure the temperature of the secondary battery or the charger/discharger. In contrast, the temperature measurement part may not be disposed in the secondary battery or the charger/discharger, and may measure the temperature of the secondary battery or the charger/discharger in a non-contact manner. The present disclosure does not limit the temperature measurement method. The temperature measurement part may transmit information on the temperature of the secondary battery and the temperature of the charger/discharger measured to the control part.

Next, a processor (e.g., the processor 210 of the control part 200) may determine whether the temperature of the charger/discharger received is lower than or equal to the temperature of the secondary battery (act S820). In response to determining that the temperature of the charger/discharger received is lower than or equal to the temperature of the secondary battery (Yes), the processor may heat the charger/discharger (act S830). Here, the processor may heat the charger/discharger by transmitting a control signal for instructing heating to the temperature adjustment part. The temperature adjustment part may heat the charger/discharger by performing the operation of a heating device included in the temperature adjustment part in response to receiving the control signal. In embodiments, the heating device may include at least one of a wire heater, a ribbon heater, or a film heater.

In response to determining that the temperature of the charger/discharger received is higher than the temperature of the secondary battery (No), the processor may cool the charger/discharger (act S840). Here, the processor may cool the charger/discharger by transmitting a control signal for instructing cooling to the temperature adjustment part. The temperature adjustment part may cool the charger/discharger by performing the operation of a cooling device included in the temperature adjustment part in response to receiving the control signal. In embodiments, the cooling device may include at least one of a cooling flow path or a thermoelectric element.

The flowchart in FIG. 8 and the foregoing description are merely examples of the present disclosure, and the scope of the present disclosure is not limited to the flowchart in FIG. 8 and the foregoing description. For example, one or more steps in the flowchart and the foregoing description may be added, modified, and/or deleted, the order of one or more steps may be changed, and one or more steps may be performed simultaneously.

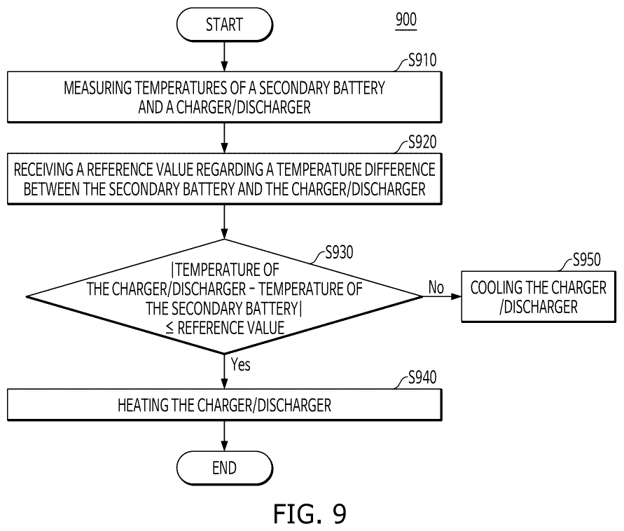

FIG. 9 is a flowchart showing an example in which a method 900 of adjusting the temperature of a charger/discharger is performed according to embodiments of the present disclosure.

First, the method 900 of adjusting the temperature of a charger/discharger may begin by measuring the temperatures of a secondary battery and a charger/discharger (act S910). Here, the temperatures of the secondary battery and the charger/discharger may be measured by a temperature measurement part. In embodiments, the temperature measurement part may be disposed in the secondary battery or the charger/discharger and may measure the temperature of the secondary battery or the charger/discharger. In contrast, the temperature measurement part may not be disposed in the secondary battery or the charger/discharger, and may measure the temperature of the secondary battery or the charger/discharger in a non-contact manner. The present disclosure does not limit the temperature measurement method. The temperature measurement part may transmit information on the temperature of the secondary battery and the temperature of the charger/discharger measured to the control part.

Next, the control part may receive a reference value regarding the temperature difference between the secondary battery and the charger/discharger (act S920). Here, the reference value regarding the temperature difference between the secondary battery and the charger/discharger may be a value obtained based on temperature information according to the charging and discharging conditions of a secondary battery module unit. The control part may store the received reference value regarding the temperature difference between the secondary battery and the charger/discharger in a memory (e.g., the memory 220 of the control part 200). The control part may receive the reference value regarding the temperature difference between the secondary battery and the charger/discharger from an external device capable of communicating with the control part. However, the present disclosure is not limited thereto.

Next, a processor (e.g., the processor 210 of the control part 200) may determine whether the difference between the temperature of the charger/discharger and the temperature of the secondary battery received is less than or equal to the reference value (act S930). In response to determining that the difference between the temperature of the charger/discharger and the temperature of the secondary battery received is less than or equal to the reference value (Yes), the processor may heat the charger/discharger (act S940). Here, the processor may heat the charger/discharger by transmitting a control signal for instructing heating to the temperature adjustment part. The temperature adjustment part may heat the charger/discharger by performing the operation of a heating device included in the temperature adjustment part in response to receiving the control signal. In embodiments, the heating device may include at least one of a wire heater, a ribbon heater, or a film heater.

In response to determining that the difference between the temperature of the charger/discharger and the temperature of the secondary battery received is higher than the reference value (No), the processor may cool the charger/discharger (act S950). Here, the processor may cool the charger/discharger by transmitting a control signal for instructing cooling to the temperature adjustment part. The temperature adjustment part may cool the charger/discharger by performing the operation of a cooling device included in the temperature adjustment part in response to receiving the control signal. In embodiments, the cooling device may include at least one of a cooling flow path or a thermoelectric element.

The flowchart in FIG. 9 and the foregoing description are merely examples of the present disclosure, and the scope of the present disclosure is not limited to the flowchart in FIG. 9 and the foregoing description. For example, one or more steps in the flowchart and the foregoing description may be added, modified, and/or deleted, the order of one or more steps may be changed, and one or more steps may be performed simultaneously.

The preferred embodiments of the present disclosure described herein are disclosed for the purpose of illustration, those having ordinary skill in the art of the present disclosure will be able to make various modifications, changes, and additions within the spirit and scope of the present disclosure, and such modifications, changes, and additions should be considered to fall within the scope of the patent claims.

Those having ordinary skill in the art to which the present disclosure pertains can make various substitutions, modifications, and changes without departing from the technical ideas of the present disclosure, and therefore the present disclosure is not limited by the foregoing embodiments and the accompanying drawings.

Although the present disclosure has been described above with respect to embodiments thereof, the present disclosure is not limited thereto. Various modifications and variations can be made thereto by those skilled in the art within the spirit of the present disclosure and the equivalent scope of the appended claims.

What is claimed is:

1. A secondary battery monitoring device comprising:
a charger/discharger connected to electrode terminals of a secondary battery and configured to measure a voltage of the secondary battery or apply a current to the secondary battery;
a temperature measurement part configured to measure a temperature of the secondary battery and a temperature of the charger/discharger;
a temperature adjustment part configured to adjust the temperature of the charger/discharger; and
a control part configured to control the temperature adjustment part,
wherein the control part is configured to adjust the temperature of the charger/discharger by controlling the temperature adjustment part based on temperature information received from the temperature measurement part.

2. The secondary battery monitoring device as claimed in claim 1, wherein the temperature adjustment part comprises a heating device disposed in the charger/discharger, and
wherein the control part is further configured to heat the charger/discharger by controlling the heating device if the temperature of the charger/discharger received from the temperature measurement part is lower than or equal to the temperature of the secondary battery.

3. The secondary battery monitoring device as claimed in claim 1, wherein the temperature adjustment part comprises a cooling device disposed in the charger/discharger, and
wherein the control part is further configured to cool the charger/discharger by controlling the cooling device if the temperature of the charger/discharger received from the temperature measurement part is higher than the temperature of the secondary battery.

4. The secondary battery monitoring device as claimed in claim 2, wherein the heating device comprises at least one of a wire heater, a ribbon heater, or a film heater.

5. The secondary battery monitoring device as claimed in claim 3, wherein the cooling device comprises at least one of a cooling flow path or a thermoelectric element.

6. The secondary battery monitoring device as claimed in claim 1, wherein:
the secondary battery comprises a first electrode terminal and a second electrode terminal,
the charger/discharger comprises a first electrode pin and a second electrode pin,
the first electrode pin is connected to the first electrode terminal, and
the second electrode pin is connected to the second electrode terminal.

7. The secondary battery monitoring device as claimed in claim 1, wherein the control part is further configured to receive a reference value regarding a temperature difference between the secondary battery and the charger/discharger.

8. The secondary battery monitoring device as claimed in claim 7, wherein the reference value is a value obtained based on temperature information according to charging/discharging conditions of a secondary battery module unit.

9. The secondary battery monitoring device as claimed in claim 7, wherein the temperature adjustment part comprises a heating device, and
wherein the control part is further configured to heat the charger/discharger by controlling the heating device if the temperature difference between the charger/discharger and the secondary battery received from the temperature measurement part is less than or equal to the reference value.

10. The secondary battery monitoring device as claimed in claim 7, wherein the temperature adjustment part comprises a cooling device, and
wherein the control part is further configured to cool the charger/discharger by controlling the cooling device if the temperature difference between the charger/discharger and the secondary battery received from the temperature measurement part is higher than the reference value.

11. A method of monitoring a secondary battery, comprising:
performing charging and discharging of a secondary battery by a charger/discharger connected to electrode terminals of the secondary battery;
measuring a temperature of the secondary battery and a temperature of the charger/discharger; and
adjusting the temperature of the charger/discharger based on the measured temperature of the secondary battery and the measured temperature of the charger/discharger.

12. The method as claimed in claim 11, wherein the adjusting of the temperature of the charger/discharger comprises:
heating the charger/discharger in response to determining that the temperature of the charger/discharger is lower than or equal to the temperature of the secondary battery.

13. The method as claimed in claim 11, wherein the adjusting of the temperature of the charger/discharger comprises:
cooling the charger/discharger in response to determining that the temperature of the charger/discharger is higher than the temperature of the secondary battery.

14. The method as claimed in claim 12, wherein the charger/discharger is heated by at least one of a wire heater, a ribbon heater, or a film heater installed in the charger/discharger.

15. The method as claimed in claim 13, wherein the charger/discharger is cooled by at least one of a cooling flow path or a thermoelectric element installed in the charger/discharger.

16. The method as claimed in claim 11, wherein:
the secondary battery comprises a first electrode terminal and a second electrode terminal,
the charger/discharger comprises a first electrode pin and a second electrode pin,
the first electrode pin is connected to the first electrode terminal, and
the second electrode pin is connected to the second electrode terminal.

17. The method as claimed in claim 11, further comprising:
receiving a reference value regarding a temperature difference between the secondary battery and the charger/discharger.

18. The method as claimed in claim 17, wherein the reference value is a value obtained based on temperature information according to charging/discharging conditions of a secondary battery module unit.

19. The method as claimed in claim 17, wherein the adjusting the temperature of the charger/discharger comprises:
heating the charger/discharger in response to determining that the temperature difference between the charger/discharger and the secondary battery is less than or equal to the reference value.

20. The method as claimed in claim 17, wherein the adjusting of the temperature of the charger/discharger comprises:
cooling the charger/discharger in response to determining that the temperature difference between the charger/discharger and the secondary battery is higher than the reference value.
